(19) United States
(12) Patent Application Publication
(10) Pub. No.: US 2014/0286093 A1
(43) Pub. Date: Sep. 25, 2014

(54) SEMICONDUCTOR MEMORY DEVICE

(71) Applicant: Kabushiki Kaisha Toshiba, Minato-ku (JP)

(72) Inventors: Katsumi Abe, Kanagawa-ken (JP); Masahiro Yoshihara, Kanagawa-ken (JP)

(73) Assignee: Kabushiki Kaisha Toshiba, Minato-ku (JP)

(21) Appl. No.: 14/022,729

(22) Filed: Sep. 10, 2013

(30) Foreign Application Priority Data
Mar. 22, 2013 (JP) 2013-061125

(51) Int. Cl. G11C 16/04

(52) U.S. Cl. CPC G11C 16/0408
USPC 365/185.03

(57) ABSTRACT

According to one embodiment, a semiconductor memory device includes a NAND string and a sense amplifier. The NAND string includes a memory cell transistor to be capable of holding any of three or more levels of values. The NAND string includes one end connected to a bit line and the other end connected to a source line. The sense amplifier connects the bit line. A first voltage is applied to the source line when a first read voltage is applied to a selected word line connected to a selected memory cell transistor. A second voltage is applied to the source line when a second read voltage is applied to the selected word line. The first voltage is higher than the second voltage. The first read voltage is the lowest voltage of a plurality of read voltage. The second read voltage is higher than the first read voltage.

### CROSS REFERENCE TO RELATED APPLICATION

This application is based upon and claims the benefit of priority from the prior Japanese Patent Application No. 2013-061125, filed on Mar. 22, 2013, the entire contents of which are incorporated herein by reference.

### FIELD

Embodiments described herein relate to a semiconductor memory device.

### BACKGROUND

A recent NAND flash memory as a semiconductor memory device includes memory cells each writing any one of four levels of values and thereby storing two bits of data.

### BRIEF DESCRIPTION OF THE DRAWINGS

FIG. 1 is a circuit diagram illustrating a semiconductor memory device according to an embodiment;

FIG. 2 is a diagram illustrating threshold voltage distributions of each memory cell transistor according to the embodiment;

FIG. 3(a) to FIG. 3(c) are circuit diagrams showing voltages applied to the memory cell transistor, where FIG. 3(a) illustrates “Read-A,” FIG. 3(b) illustrates “Read-B,” and FIG. 3(c) illustrates “Read-C”;

FIG. 4 is a timing chart illustrating read operations of the semiconductor memory device according to the embodiment;

FIG. 5(a) and FIG. 5(b) are circuit diagrams showing voltages applied to an N-channel transistor NT3, where FIG. 5(a) illustrates a case where a cell source voltage is a voltage V2, whereas FIG. 5(b) illustrates a case where the cell source voltage is a voltage V1;

FIG. 6 is a diagram illustrating threshold voltage distributions of each memory cell transistor in a first comparative example for the embodiment;

FIG. 7 is a diagram illustrating threshold voltage distributions of each memory cell transistor in a second comparative example for the embodiment; and

FIG. 8 is a diagram illustrating threshold voltage distributions of each memory cell transistor in a third comparative example for the embodiment.

### DETAILED DESCRIPTION

According to one embodiment, a semiconductor memory device includes a NAND string and a sense amplifier. The NAND string includes a memory cell transistor to be capable of holding any of three or more levels of values. The NAND string includes one end connected to a bit line and the other end connected to a source line. The sense amplifier connects the bit line. A first voltage is applied to the source line when a first read voltage is applied to a selected word line connected to a selected memory cell transistor. A second voltage is applied to the source line when a second read voltage is applied to the selected word line. The first voltage is higher than the second voltage. The first read voltage is the lowest voltage of a plurality of read voltage. The second read voltage is higher than the first read voltage.

Hereinafter, a plurality of embodiments are further described in reference to the drawings. In the drawings, the same reference signs are attached to the same or similar portions. In the following description, “connect to an element” means “connect to an element via another element” as well as “connect to an element directly.”

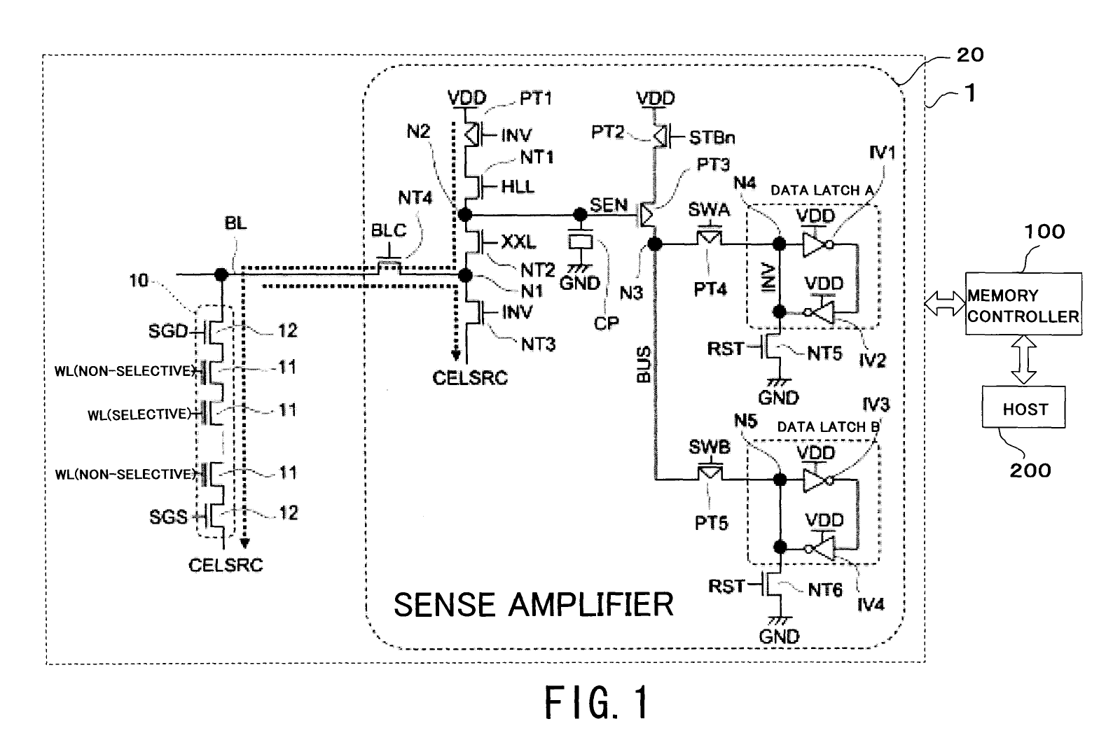

A semiconductor memory device according to an embodiment is described with reference to the drawings. FIG. 1 is a circuit diagram illustrating a semiconductor memory device. The semiconductor memory device according to the embodiment is a NAND flash memory.

As illustrated in FIG. 1, the semiconductor memory device 1 includes a plurality of NAND strings 10 and a plurality of sense amplifiers 20. FIG. 1 shows only one NAND string 10 and one sense amplifier 20 for simplification of explanation. A bit line BL is drawn from the sense amplifier 20.

Data and signals are received on one another between a host 200 and a memory controller 100. Data and signals are received on one another between the memory controller 100 and the semiconductor memory device 1.

The memory controller 100 generates various commands to control the operations of the semiconductor memory device 1, an address, and data, and outputs them to the semiconductor memory device 1.

A configuration of the NAND string 10 is described.

The NAND string 10 includes a plurality of memory cell transistors 11 connected in series and two select transistors 12 respectively connected to two ends of the plurality of memory cell transistors 11. Each of the memory cell transistors 11 is a transistor including a charge storage layer, and is an N-channel floating gate transistor or an N-channel transistor having a MONOS (Metal-Oxide-Nitride-Oxide-Silicon) structure. Each of the select transistors 12 is an N-channel MOSFET (Metal-Oxide-Semiconductor Field-Effect Transistor). One end of the NAND string 10 is connected to the bit line BL and a cell source voltage CELSRC which is a voltage of a source line is applied to the other end of the NAND string 10. The gate of the memory cell transistor 11 is connected to a word line WL. A voltage SGD is applied to the gate of the select transistor 12 on the bit line BL side. A voltage SGS is applied to the gate of the select transistor 12 on the cell source side. It should be noted that “connect” in the specification means that two objects have a relationship where an electric current can flow between the objects, and includes both a case where the two objects are in direct contact with each other, and a case where the objects are indirectly coupled to each other via a conductor or semiconductor.

A configuration of the sense amplifier 20 is described.

The sense amplifier 20 includes P-channel transistors PT1 to PT5, N-channel transistors NT1 to NT6, a capacitor CP, a data latch A, and a data latch B. The P-channel transistor PT1 (second transistor), the N-channel transistor NT1 (third transistor), the N-channel transistor NT2 (fourth transistor) and the N-channel transistor NT3 (first transistor) are connected in series between a power supply voltage VDD and the cell source voltage CELSRC. All of the P-channel transistors PT1 to PT5 and the N-channel transistors NT1 to NT6 are MOSFETs. Other transistors described later are also MOSFETs. The cell source voltage CELSRC is a voltage equal to or higher than a ground voltage GND. The power supply voltage VDD is higher than the cell source voltage CELSRC. One end of the N-channel transistor NT4 is connected to a node N1 between the N-channel transistor NT2 and the N-channel transistor NT3, and the other end of the N-channel transistor NT4 is connected to the bit line BL.

A voltage INV is applied to the gate of the P-channel transistor PT1. The voltage INV is a first hold voltage to be held in the data latch A as described later. A voltage HLL (third voltage) is applied to the gate of the N-channel transistor NT1. A voltage XXL (fourth voltage) is applied to the gate of the N-channel transistor NT2. The voltage INV is applied to the gate of the N-channel transistor NT3. A voltage BLC is applied to the gate of the N-channel transistor NT4.

One end of the capacitor CP is connected to a node N2 between the N-channel transistor NT1 and the N-channel transistor NT2, and the ground voltage GND is applied to the other end of the capacitor CP.

The P-channel transistor PT2 and the P-channel transistor PT3 connected in series are provided between the power supply voltage VDD and a node N3. A voltage STBn is applied to the gate of the P-channel transistor PT2. A voltage SEN of the node N2 is applied to the gate of the P-channel transistor PT3.

The P-channel transistor PT4, the data latch A, and the N-channel transistor NT5 are connected in series between the node N3 and the ground voltage GND. A node N4 between the P-channel transistor PT4 and the N-channel transistor NT5 is a portion of the data latch A. In the data latch A, an inverter IV1 and an inverter IV2 are connected to each other in a loop. The data latch A generates the first hold voltage (voltage of the node N4). An input side of the inverter IV1 is connected to the node N4. An output side of the inverter IV1 is connected to an input side of the inverter IN2. An output side of the inverter IV2 is connected to the node N4. A voltage SWA is applied to the gate of the P-channel transistor PT4. A voltage RST is applied to the gate of the N-channel transistor NT5. The voltage of the node N4 is the foregoing voltage INV.

Similarly, the P-channel transistor PT5, the data latch B and the N-channel transistor NT6 are connected in series between the node N3 and the ground voltage GND. A node N5 between the P-channel transistor PT5 and the N-channel transistor NT6 is a portion of the data latch B. In the data latch B, an inverter IV3 and an inverter IV4 are connected to each other in a loop. The data latch B generates a second hold voltage (voltage of the node N5). An input side of the inverter IV3 is connected to the node N5. An output side of the inverter IV3 is connected to an input side of the inverter IN4. An output side of the inverter IV4 is connected to the node N5. A voltage SWB is applied to the gate of the P-channel transistor PT5. The voltage RST is applied to the gate of the N-channel transistor NT6. The voltage of the node N5 is different from the voltage INV. An auxiliary latch circuit provided to temporarily save a sense result or to perform calculation with data held in the data latch A, for example, may be used as the data latch B.

The data latch A and the data latch B are connected in parallel between the node N3 and the ground voltage GND. The connection between the node N3 and the data latch A is controlled by the P-channel transistor PT4. The connection between the node N3 and the data latch B is controlled by the P-channel transistor PT5. The voltage of the node N3 is controlled by the P-channel transistor PT3. The conduction of the P-channel transistor PT3 is determined by the voltage SEN of the node N2.

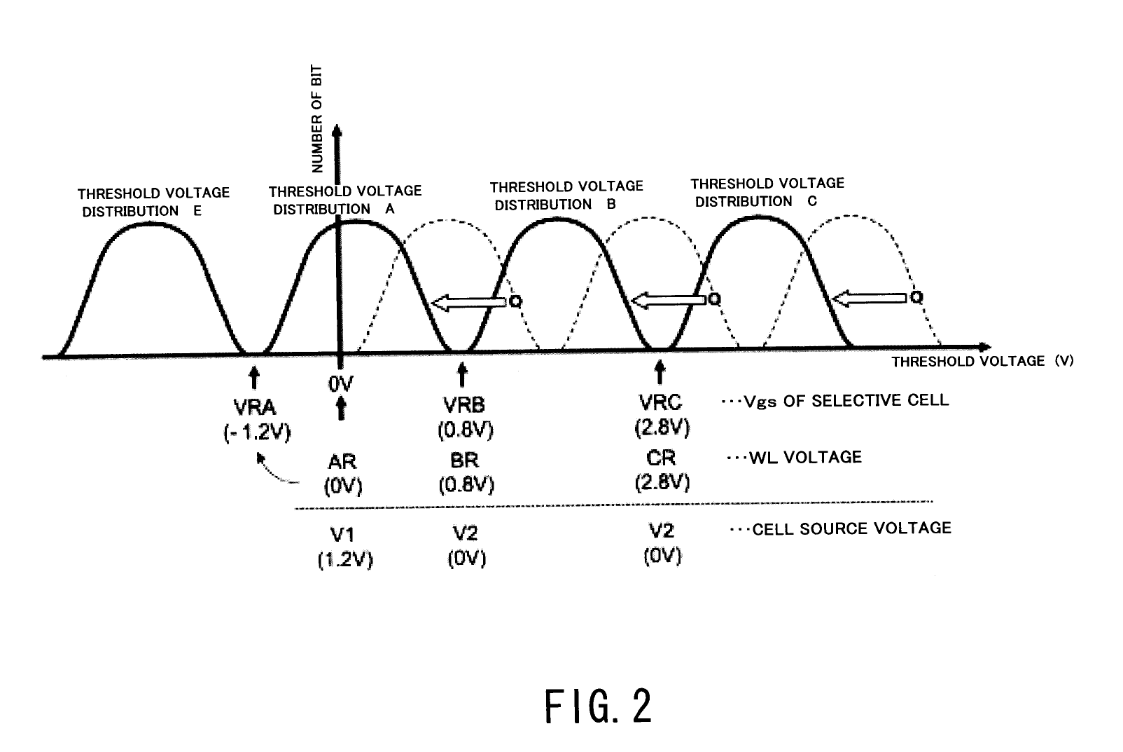

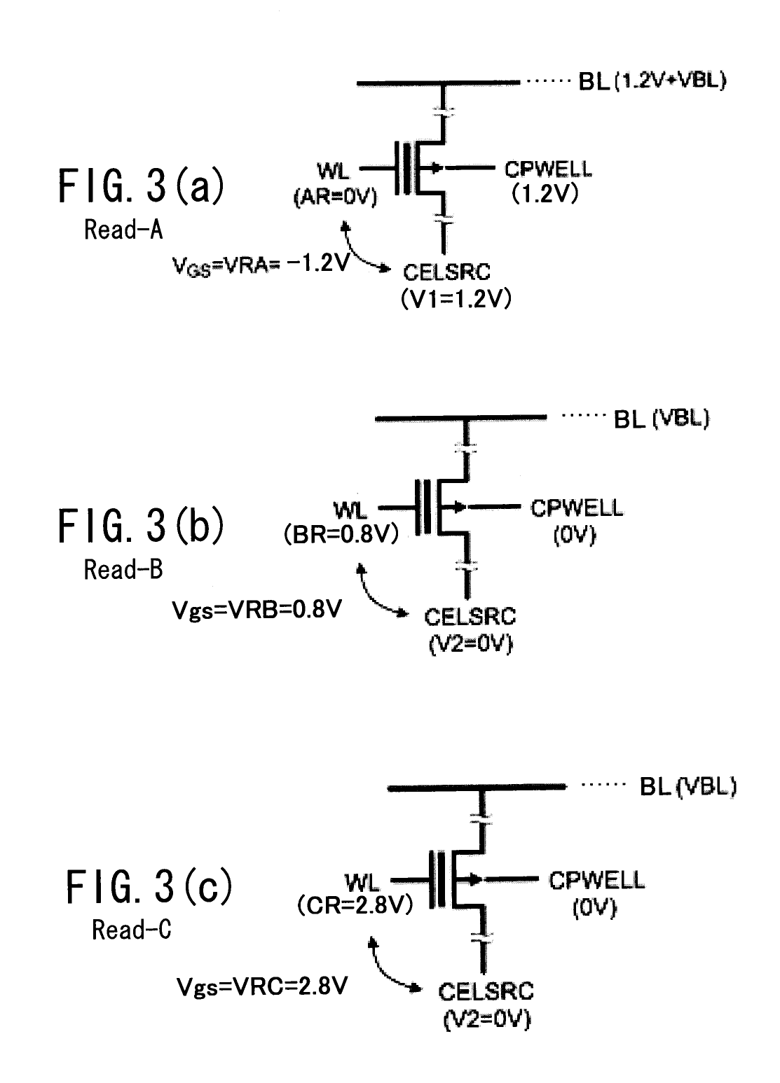

Next, operations of the semiconductor memory device according to the embodiment are described. FIG. 2 is a diagram illustrating threshold voltage distributions of each memory cell transistor. In FIG. 2, a horizontal axis indicates a threshold voltage and a vertical axis indicates a frequency (the number of bit). FIGS. 3(a) to 3(c) are circuit diagrams illustrating voltages applied to the memory cell transistor. FIG. 3(a) illustrates “Read-A,” FIG. 3(b) illustrates “Read-B,” and FIG. 3(c) illustrates “Read-C.”

As illustrated in FIG. 2, in the memory cell transistor 11, the threshold voltages are set to have four threshold voltage distributions respectively for four levels of values to be stored by the memory cell transistor 11. The threshold voltage distributions of each memory cell transistor include a threshold voltage distribution E in an erased state, and also three threshold voltage distributions which are called, in ascending order of threshold voltage, a threshold voltage distribution A, a threshold voltage distribution B, and a threshold voltage distribution C. In reading a value written in the memory cell transistor 11, a read voltage is applied between the gate and the source of the memory cell transistor 11. The read voltage is set such that a gate-to-source voltage of the memory cell transistor 11 can have a value at a valley between adjacent two of the threshold voltage distributions. A relevant threshold voltage is judged as lower than the read voltage when the memory cell transistor 11 is brought into conduction, or the relevant threshold voltage is judged as higher than the read voltage when the memory cell transistor 11 is not brought into conduction.

More specifically, in order to identify whether a value written in a certain memory cell transistor 11 corresponds to the threshold voltage distribution E, or corresponds to any one of the threshold voltage distribution A, the threshold voltage distribution B and the threshold voltage distribution C, a read voltage AR is applied to the gate of the memory cell transistor 11 such that the gate-to-source voltage can be a voltage between the threshold voltage distribution E and the threshold voltage distribution A. When the memory cell transistor 11 is brought into conduction, the relevant threshold voltage is judged as falling under the threshold voltage distribution E; whereas, when the memory cell transistor 11 is not brought into conduction, the relevant threshold voltage is judged as falling under the threshold voltage distribution A, the threshold voltage distribution B or the threshold voltage distribution C. Hereinafter, the above operation is referred to as “Read-A.”

In order to identify whether the value written in a certain memory cell transistor 11 corresponds to any one of the threshold voltage distribution E and the threshold voltage distribution A, or corresponds to any one of the threshold voltage distribution B and the threshold voltage distribution C, a read voltage BR is applied to the gate of the memory cell transistor 11 such that the gate-to-source voltage can be a voltage between the threshold voltage distribution A and the threshold voltage distribution B. When the memory cell transistor 11 is brought into conduction, the relevant threshold voltage is judged as falling under the threshold voltage distribution E or the threshold voltage distribution A; whereas, when the memory cell transistor 11 is not brought into conduction, the relevant threshold voltage is judged as falling under the threshold voltage distribution B or the threshold voltage distribution C. Hereinafter, the above operation is referred to as “Read-B.”

In order to identify whether the value written in a certain memory cell transistor 11 corresponds to any one of the threshold voltage distribution E, the threshold voltage distribution A and the threshold voltage distribution B, or corresponds to the threshold voltage distribution C, a read voltage CR is applied to the gate of the memory cell transistor 11 such that the gate-to-source voltage be a voltage between the threshold voltage distribution B and the threshold voltage distribution C. When the memory cell transistor 11 is brought into conduction, the threshold voltage is judged as falling under the threshold voltage distribution E, the threshold voltage distribution A or the threshold voltage distribution B; whereas, when the memory cell transistor 11 is not brought into conduction, the threshold voltage is judged as falling under the threshold voltage distribution C. Hereinafter, the above operation is referred to as “Read-C.”

In the embodiment, the voltage between gate and source of the memory cell transistor 11 in the “Read-A” (hereinafter referred to as the “read voltage VRA”) is a negative voltage. The voltage between gate and source of the memory cell transistor 11 in the “Read-B” (hereinafter referred to as the “read voltage VRB”) and the voltage between gate and source of the memory cell transistor 11 in the “Read-C” (hereinafter referred to as the “read voltage VRC”) are positive voltages. For example, the read voltage VRA is −1.2V, the read voltage VRB is +0.8V, and the read voltage VRC is +2.8V. In the case of applying the read voltage VRA, the cell source voltage CELSRC and a back-gate voltage CPWELL are set to a positive voltage V1 (first voltage). In the case of applying the read voltage VRB and the read voltage VRC, the cell source voltage CELSRC and the back-gate voltage CPWELL are set to the a voltage V2 (second voltage) that is equal to or higher than the ground voltage (0V) but lower than the voltage V1.

Specifically, as illustrated in FIG. 2 and FIG. 3(a), in order to apply the read voltage VRA to the memory cell transistor 11, the cell source voltage CELSRC is set to the voltage V1 (+1.2V, for example), the back-gate voltage CPWELL is set to +1.2V, the voltage of the bit line BL is set to a voltage (VBL+1.2V), and the read voltage AR applied to the word line WL is set to 0V. As a result, in the memory cell transistor 11, the gate voltage is low relative to the source voltage. Thus, −1.2V can be obtained as the read voltage VAR without use of a negative voltage as the read voltage AR. In addition, the voltage between the bit line BL and the cell source can be set to VBL.

In contrast, as illustrated in FIG. 2 and FIG. 3(b), in order to apply the read voltage VRB to the memory cell transistor 11, the cell source voltage CELSRC is set to the voltage V2 (0V, for example), the back-gate voltage CPWELL is set to 0V, the voltage of the bit line BL is set to the voltage VBL, and the read voltage BR applied to the word line WL is set to 0.8V. As a result, the cell source voltage CELSRC and the back-gate voltage CPWELL can be set to the ground voltage, and the read voltage VRB can be set to +0.8V. In addition, the voltage between the bit line BL and the cell source can be set to VBL.

Similarly, as illustrated in FIG. 2 and FIG. 3(c), in order to apply the read voltage VRC to the memory cell transistor 11, the cell source voltage CELSRC is set to the voltage V2 (0V, for example), the back-gate voltage CPWELL is set to 0V, the voltage of the bit line BL is set to the voltage VBL, and the read voltage CR applied to the word line WL is set to 2.8V. As a result, the cell source voltage CELSRC and the back-gate voltage CPWELL can be set to the ground voltage, and the read voltage VRC can be set to +2.8V. In addition, the voltage between the bit line BL and the cell source can be set to VBL.

Here, read operations of the semiconductor memory device 1 are explained in time series order.

A control method of the embodiment is referred to as “A” only Deep Negative method (AODN method).

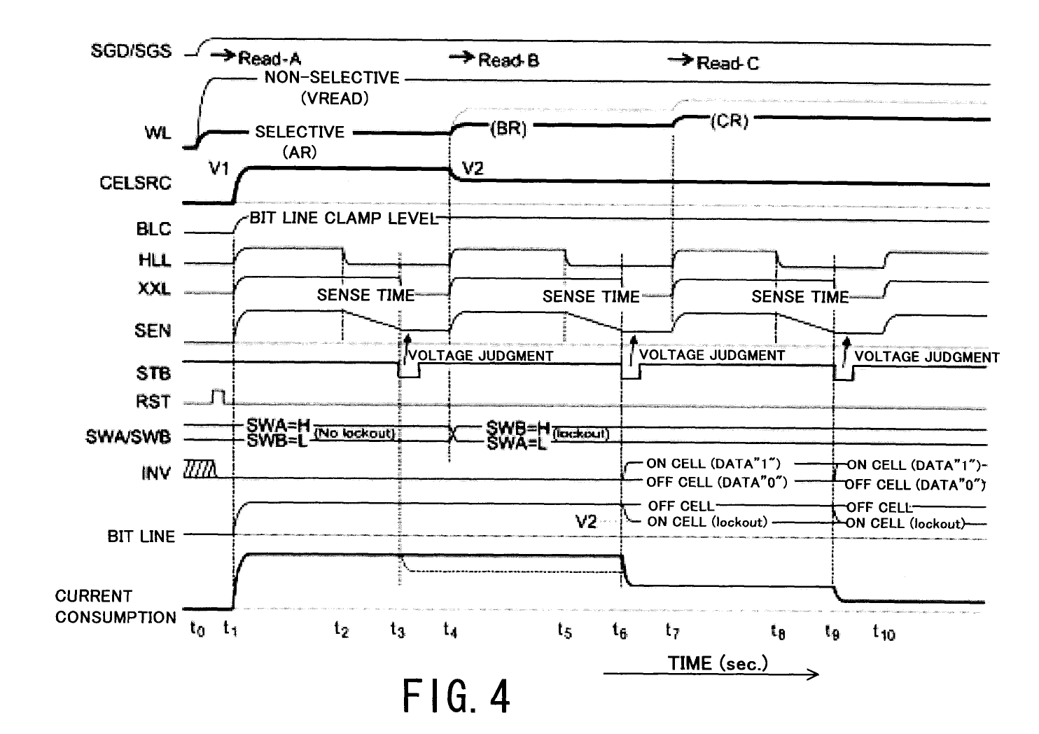

The following description is provided mainly by referring to FIGS. 1 and 4. FIG. 4 is a timing chart illustrating the read operations of the semiconductor memory device.

Firstly, the operation “Read-A” is executed.

As illustrated in FIG. 4, at a time t₀, the voltage of the word line WL connected to the gate of a memory cell transistor 11 targeted for data reading (hereinafter also referred to as the “selective cell”) is set to the read voltage AR, and the voltages of the work lines WL connected to the gates of the other memory cell transistors 11 (hereinafter also referred to as the “non-selective cells”) are set to a non-selective voltage VREAD. The non-selective voltage VREAD is a relatively-high voltage which turns on the non-selective cells (in an in-conduction state) regardless the values written in the non-selective cells. In addition, the voltage SGD and the voltage SGS are raised to a high level (H) and thereby both the select transistors 12 are turned on.

In this operation, the voltage RST is raised to the high level (H), and thereby the N-channel transistor NT5 and the N-channel transistor NT6 are turned on to cause the data latch A and the data latch B to hold the ground voltage GND as the hold voltages. As a result, the voltage INV becomes at a low level (L), and the P-channel transistor PT1 is turned on while the N-channel transistor NT3 is turned off (in an out-of-conduction state). Thereafter, the voltage RST is returned to the low level (L), and thereby the N-channel transistors NT5 and NT6 are returned to the off state.

In this operation, all of the voltage BLC, the voltage HLL, and the voltage XXL are set to the low level. As a result, the N-channel transistor NT4, the N-channel transistor NT1 and the N-channel transistor NT2 are in the off state. The P-channel transistor PT2 is in the off state with the voltage STBn set to the high level. The P-channel transistor PT4 is in the off state with the voltage SWA set to the high level, while the P-channel transistor PT5 is in the on state with the voltage SWB set to the low level. As a result, all the nodes N1 to N5 are in the floating state.

At a time t₁, the cell source voltage CELSRC is raised to the voltage V1 (+1.2V, for example). The voltage BLC, the voltage HLL, and the voltage XXL are raised to the high level. As a result, all of the N-channel transistor NT4, the N-channel transistor NT1, and the N-channel transistor NT2 are turned on. One end of the NAND string 10 is connected to the power supply voltage VDD, and the other end of the NAND string 10 is connected to the cell source voltage CELSRC. For this reason, a cell current flows through the NAND string 10 from the bit line BL to the cell source. Meanwhile, the voltage SEN of the node N2 is raised to the power supply voltage VDD and the P-channel transistor PT3 is turned off. Thus, the capacitor CP is charged.

In this operation, as illustrated in FIG. 3(a), the read voltage VRA of −1.2V, for example, is applied between the gate and the source of the selective cell. As a result, when the value of the selective cell corresponds to the threshold voltage distribution E, the selective cell is turned on and the electrical resistivity of the whole NAND string 10 becomes relatively low. On the other hand, when the value of the selective cell corresponds to the threshold voltage distribution A, the threshold voltage distribution B or the threshold voltage distribution C, the selective cell is turned off and the electrical resistivity of the whole NAND string 10 becomes relatively high.

At a time t₂, after the voltage of the bit line BL reaches equilibrium, the voltage HLL is lowered to the low level. As a result, the N-channel transistor NT1 is turned off and the node N2 is cut off from the power supply voltage VDD. After that, the electric charge accumulated in the capacitor CP flows into the cell source through the bit line BL and the NAND string 10. In this operation, when the value of the selective cell corresponds to the threshold voltage distribution E, the electrical resistivity of the whole NAND string 10 is relatively low, so that the electric charge of the capacitor CP is discharged relatively fast and accordingly the voltage SEN declines relatively fast. On the other hand, when the value of the selective cell corresponds to the threshold voltage distribution A, the threshold voltage distribution B or the threshold voltage distribution C, the electrical resistivity of the NAND string 10 is relatively high, so that the electric charge of the capacitor CP is discharged relatively slowly and accordingly the voltage SEN declines relatively slowly.

Thus, at a time t₃ which is a fixed sense time after the time t₂, the voltage SEN in a moment when the N-channel transistor NT2 is turned off by lowering the voltage XXL to the low level is relatively low when the value of the selective cell falls under the threshold voltage distribution E, or is relatively high when the value of the selective cell falls under the threshold voltage distribution A, the threshold voltage distribution B or the threshold voltage distribution C. Thus, when a time interval between the time t₂ and the time t₃ and a threshold of the P-channel transistor PT3 are set appropriately, the P-channel transistor PT3 is turned on when the value of the selective cell falls under the threshold voltage distribution E, and the P-channel transistor PT3 is turned off when the value of the selective cell falls under the threshold voltage distribution A, the threshold voltage distribution B or the threshold voltage distribution C.

As a result, since the P-channel transistor PT4 is in the off state while the P-channel transistor PT5 is in the on state, the data latch B holds any one of the following voltages when the P-channel transistor PT2 is turned on by lowering the voltage STBn to the low level. Specifically, when the value of the selective cell falls under the threshold voltage distribution E, the power supply voltage VDD is written into the data latch B. On the other hand, when the value of the selective cell falls under the threshold voltage distribution A, the threshold voltage distribution B or the threshold voltage distribution C, the data latch B maintains the ground voltage GND as the second hold voltage. In the aforementioned way, the judgment result for the selective cell is written into the data latch B.

At this time point, when the second hold voltage held in the data latch B is the power supply voltage, the value of the selective cell corresponds to the threshold voltage distribution E; or when the second hold voltage held in the data latch B is the ground voltage, the value of the selective cell corresponds to the threshold voltage distribution A, the threshold voltage distribution B or the threshold voltage distribution C. Thus, when the value of the selective cell is the value corresponding to the threshold voltage distribution E, the value is determined at this time point. Thereafter, the voltage STBn is returned to the high level to return the P-channel transistor PT2 to the off state. It should be noted that the second hold voltage written in the data latch B has nothing to do with the voltage INV, and therefore does not stop the cell current from flowing no matter what value the selective cell holds.

Next, the operation “Read-B” is executed. At a time t₄, the voltage of the word line WL connected to the gate of the selective cell is raised to the read voltage BR (+0.8V, for example), and the cell source voltage CELSRC is lowered to the voltage V2 (0V, for example). Consequently, as illustrated in FIG. 3(b), the read voltage VRB of +0.8V, for example, is applied between the gate and the source of the selective cell. Then, when the value of the selective cell corresponds to the threshold voltage distribution E or the threshold voltage distribution A, the selective cell is turned on and the electrical resistivity of the whole NAND string 10 becomes relatively low. On the other hand, when the value of the selective cell corresponds to the threshold voltage distribution B or the threshold voltage distribution C, the selective cell is turned off and the electrical resistivity of the whole NAND string 10 becomes relatively high.

The voltage SWA and the voltage SWB are inverted. To be more specific, the voltage SWA is lowered to the low level to turn on the P-CHANNEL transistor PT4, while the voltage SWB is raised to the high level to turn off the P-channel transistor PT5. The voltage FILL and the voltage XXL are raised to the high level as in the time t₁. As a result, the N-channel transistor NT1 and the N-channel transistor NT2 are turned on, so that the cell current flows through the NAND string 10 and the capacitor CP is charged.

At a time t₅, the voltage HLL is lowered to the low level as in the time t₂. Thereby, the bit line BL is cut off from the power supply voltage VDD and then the electric charge accumulated in the capacitor CP flows into the cell source through the NAND string 10. As a result, the voltage SEN declines along with the discharge of the capacitor CP. The speed of the voltage decline depends on the value of the selective cell. The voltage declines relatively fast when the value of the selective cell corresponds to the threshold voltage distribution E or the threshold voltage distribution A, or declines relatively slowly when the value of the selective cell corresponds to the threshold voltage distribution B or the threshold voltage distribution C.

At a time t₆ which is the fixed sense time after the time t₅, the N-channel transistor NT2 is turned off by lowering the voltage XXL to the low level and thereby the node N2 is turned into the floating state as in the time t₃. Consequently, the P-channel transistor PT3 is turned on when the value of the selective cell corresponds to the threshold voltage distribution E or the threshold voltage distribution A, or the P-channel transistor PT3 is turned off when the value of the selective cell corresponds to the threshold voltage distribution B or the threshold voltage distribution C.

Since the P-channel transistor PT4 is in the on state while the P-channel transistor PT5 is in the off state, the data latch A holds any one of the following voltages when the P-channel transistor PT2 is turned on by lowering the voltage STBn to the low level. Specifically, when the value of the selective cell falls under the threshold voltage distribution E or the threshold voltage distribution A, the power supply voltage VDD is written into the data latch A. On the other hand, when the value of the selective cell falls under the threshold voltage distribution B or the threshold voltage distribution C, the data latch A maintains the ground voltage GND as the first hold voltage. In the aforementioned way, the judgment result for the selective cell is written into the data latch A.

At this time point, except for the case where the value of the selective cell is judged as the value corresponding to the threshold voltage distribution E at time t₃, the value of the selective cell corresponds to the threshold voltage distribution A when the first hold voltage held in the data latch A is the power supply voltage VDD; or the value of the selective cell corresponds to the threshold voltage distribution B or the threshold voltage distribution C when the first hold voltage held in the data latch A is the ground voltage GND. Thus, when the value of the selective cell is the value corresponding to the threshold voltage distribution E or the threshold voltage distribution A, the value is determined by this time point.

The first hold voltage written in the data latch A serves as the voltage INV. Accordingly, when the value of the selective cell falls under the threshold voltage distribution E or the threshold voltage distribution A, the voltage INV becomes at the high level, and thereby the P-channel transistor PT1 is turned off while the N-channel transistor NT3 is turned on. Consequently, the voltage of the bit line BL is lowered to the cell source voltage CELSRC, that is, the voltage V2, and the cell current stops flowing through the NAND string 10. The NAND string 10 in which the value of the selective cell is determined stops the cell current from flowing, and does not execute the subsequent operation. Thus, the unnecessary cell current does not flow through the NAND string 10 having the value of the selective cell thus determined, which leads to saving of current consumption. The above operation is referred to as “lockout.”

Next, the operation “Read-C” is executed.

At a time t₇, the voltage of the word line WL connected to the gate of the selective cell is raised to the read voltage CR (+2.8V, for example). The cell source voltage CELSRC is maintained at the voltage V2 (0V, for example). As illustrated in FIG. 3(c), the read voltage VRC of +2.8V, for example, is applied between the gate and the source of the selective cell. Then, when the value of the selective cell corresponds to the threshold voltage distribution E, the threshold voltage distribution A or the threshold voltage distribution B, the selective cell is turned on and the electrical resistivity of the whole NAND string 10 becomes relatively low. On the other hand, when the value of the selective cell corresponds to the threshold voltage distribution C, the selective cell is turned off and the electrical resistivity of the whole NAND string 10 becomes relatively high.

The voltage SWA is maintained at the low level and the voltage SWB is maintained at the high level. The voltage HLL and the voltage XXL are raised to the high level as in the time t₄. Thereby, the N-channel transistor NT1 and the N-channel transistor NT2 are turned on, so that the cell current flows through the NAND string 10 and the capacitor CP is charged.

At a time t₈, the voltage HLL is lowered to the low level as in the time t₅. Thereby, the bit line BL is cut off from the power supply voltage VDD and then the electric charge accumulated in the capacitor CP flows into the cell source through the NAND string 10. In this operation, the speed of the voltage SEN decline depends on the value of the selective cell. The voltage SEN declines relatively fast when the value of the selective cell corresponds to the threshold voltage distribution E, the threshold voltage distribution A or the threshold voltage distribution B, or declines relatively slowly when the value of the selective cell corresponds to the threshold voltage distribution C.

At a time t₉ which is the fixed sense time after the time t₈, the N-channel transistor NT2 is turned off by lowering the voltage XXL to the low level and thereby the node N2 is turned into the floating state as in the time t₆. Then, the P-channel transistor PT3 is turned on when the value of the selective cell corresponds to the threshold voltage distribution E, the threshold voltage distribution A or the threshold voltage distribution B, or the P-channel transistor PT3 is turned off when the value of the selective cell corresponds to the threshold voltage distribution C.

The P-channel transistor PT2 is turned on by lowering the voltage STBn to the low level. When the value of the selective cell corresponds to the threshold voltage distribution E, the threshold voltage distribution A or the threshold voltage distribution B, the power supply voltage VDD is written into the data latch A. When the value of the selective cell corresponds to the threshold voltage distribution C, the data latch A maintains the ground voltage GND as the first hold voltage. In the aforementioned way, the judgment result for the selective cell is written into the data latch A. At this time point, except for the selective cells each having the value already determined as the value corresponding to the threshold voltage distribution E or the threshold voltage distribution A, the value of the selective cell is determined as the value corresponding to the threshold voltage distribution B when the first hold voltage held in the data latch A is the power supply voltage VDD; or as the value corresponding to the threshold voltage distribution C when the first hold voltage held in the data latch A is the ground voltage GND. Thus, by this time point, the value is determined no matter what value the selective cell holds.

When the value of the selective cell falls under the threshold voltage distribution E, the threshold voltage distribution A or the threshold voltage distribution B, the voltage INV becomes at the high level, and thereby the P-channel transistor PT1 is turned off while the N-channel transistor NT3 is turned on. The voltage of the bit line BL is lowered to the cell source voltage CELSRC, that is, the voltage V2, the cell current stops flowing through the NAND string 10, and the NAND string 10 is locked out. As a result, the current consumption can be saved. When the value of the selective cell falls under the threshold voltage distribution C, the voltage INV still remains at the low level, and the cell current continues to flow. In this case, however, since the electrical resistivity of the NAND string 10 is relatively high, the current consumption is not very large.

At a time t₁₀, the voltage HLL and the voltage XXL are raised to the high level.

The operations at the time t₀ to the time t₁₀ are executed simultaneously in a plurality of NAND strings 10 and sense amplifiers 20. In each of the NAND strings 10, the operations at the time t₀ to the time t₁₀ are iterated by selecting the memory cell transistors 11 one by one as the selective cell. Thus, the values can be read from all the memory cell transistors 11.

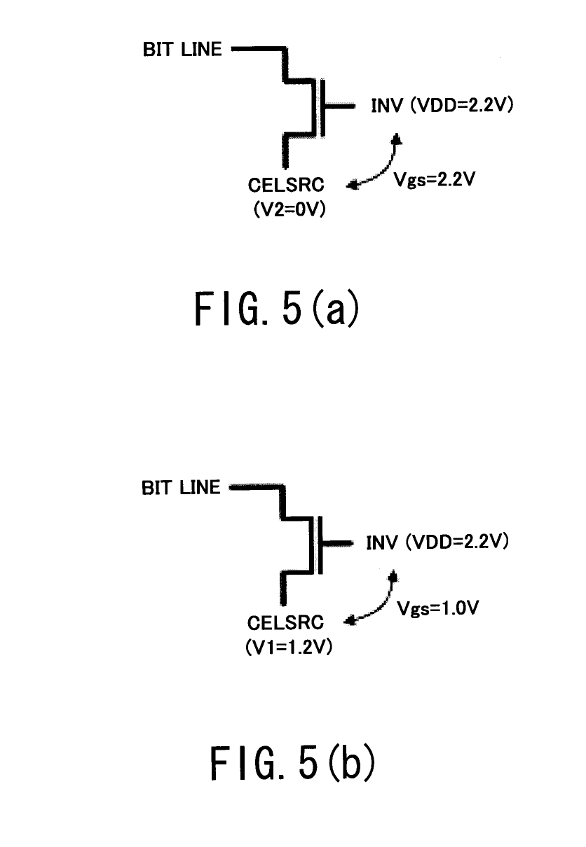

Here, effects of the embodiment are described. FIGS. 5(a) and 5(b) are circuit diagrams showing the voltages applied to the N-channel transistor NT3. FIG. 5(a) illustrates a case where the cell source voltage is the voltage V2, whereas FIG. 5(b) illustrates a case where the cell source voltage is the voltage V1.

In the embodiment, as illustrated in FIG. 2, the negative voltage is used as the read voltage VRA in the “Read-A,” and accordingly the read voltage VRC in the “Read-C” can be set lower than in the case where 0V or a positive voltage is used as the read voltage VRA. As a result, even when the memory cell transistor 11 is scaled down, it is possible to prevent leakage of the electric charge injected to the memory cell transistor 11, and thereby to avoid a shift of the threshold voltage distribution C to a lower voltage side. Thus, the semiconductor memory device 1 can guarantee high reliability even when being highly integrated.

In the embodiment, as illustrated in FIG. 2 and FIG. 3(a), the cell source voltage CELSRC in the “Read-A” is set to the positive voltage V1. Thus, the negative read voltage VRA can be obtained without use of a negative voltage as the read voltage AR. As a result, the semiconductor memory device 1 has to be provided with a positive booster to generate the positive read voltage BR and read voltage CR, but does not have to be provided with a negative booster to generate a negative read voltage AR, nor with a structure to isolate a P-channel well to which the negative voltage is applied, from a P-channel well to which the ground voltage is applied. Thus, the size and cost increase of the semiconductor memory device 1 can be prevented.

In the embodiment, as illustrated in FIG. 2 and FIGS. 3(b) and 3(c), the cell source voltage CELSRC in the “Read-B” and the “Read-C” is set to the voltage V2 that is lower than the voltage V1. The voltage INV written in the data latch A is applied to the gates of the P-channel transistor PT1 and the N-channel transistor NT3. As a result, when the power supply voltage VDD is written into the data latch A, the P-channel transistor PT1 is turned off, and a sufficiently-high positive voltage is applied between the gate and the source of the N-channel transistor NT3, as illustrated in FIG. 5(a), thereby to turn on the N-channel transistor NT3. Thus, the NAND string 10 is locked out depending on the value of the selective cell, and thereby current consumption can be saved. The NAND string 10 thus locked out has such a low electrical resistivity that the NAND string 10 produces a particularly great effect of reducing current consumption.

Since the cell source voltage CELSRC is set to the relatively low voltage V2, a higher read voltage VRC can be obtained by using a low voltage set as the read voltage CR, than in the case where the cell source voltage CELSRC is set to the relatively high voltage V1. Thus, the size reduction of the semiconductor memory device 1 can be achieved.

Moreover, in the “Read-A,” the cell source voltage CELSRC is set to the relatively high voltage V1. For this reason, when the judgment result for the selective cell were also written into the data latch A in the “Read-A”, a sufficiently-high gate-to-source voltage would not be obtained in the N-channel transistor NT3, as illustrated in FIG. 5(b), even when the voltage INV becomes the power supply voltage VDD. When the voltage V1 is 1.2V and the power supply voltage VDD is 2.2V, for example, the voltage between gate and source of the N-channel transistor NT3 is +1V. With variations in the threshold of the N-channel transistor NT3 taken into account, the voltage between gate and source may be insufficient to certainly turn on the N-channel transistor NT3 in some cases. In this case, the N-channel transistor NT3 is in an insufficient conduction state, so that the NAND string 10 supposed to be locked out cannot be locked out and the bit line BL becomes into the floating state. Being in the floating state, the bit line BL has an unstable voltage and interferes with a next bit line BL. Accordingly, an erroneous operation may occur in the reading operation from the next bit line BL.

In the embodiment, the read result in the “Read-A” is written to the data latch B instead of the data latch A. Since the data latch B has nothing to do with the voltage INV, the NAND string 10 is not locked out even when the value of the selective cell corresponds to the threshold voltage distribution E. Thus, at the time t₄, the N-channel transistor NT1 and the N-channel transistor NT2 are turned on by raising the voltage HLL and the voltage XXL to the high level, the cell current flows from the power supply voltage VDD to the cell source through the NAND string 10 because the P-channel transistor PT1 is in the on state and the N-channel transistor NT3 is in the off state. In this case, although a slightly-larger amount of current is consumed than in the case where the NAND string 10 is locked out, the voltage of the bit lien BL is stable since the steady current flows through the bit line BL. This prevents an erroneous read operation in the “Read-B” on a next bit line. Thus, the operation reliability of the semiconductor memory device 1 can be improved.

Next, comparative examples for the embodiment are described.

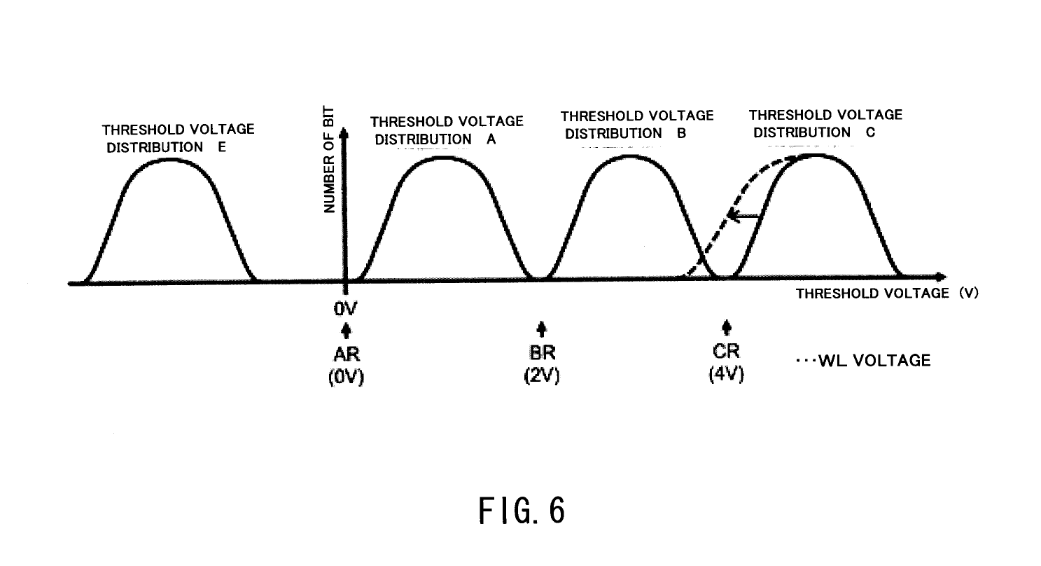

A first comparative example is described. FIG. 6 is a diagram illustrating threshold voltage distributions of each memory cell transistor of the first comparative example.

As illustrated in FIG. 6, the read voltage AR is set to 0V in the first comparative example. The method of the first comparative example is called “a positive sense method,” where all the read voltages can be set to positive values. In the first comparative example, however, the threshold voltage distribution C needs to be set within a quite high voltage range, which causes a problem that the electric charge accumulated in the memory cell transistor is more likely to leak out along with further scaling-down of the memory cell transistor. When the electric charge leaks out, the threshold voltage distribution C shifts to a lower voltage side and overlaps with the threshold voltage distribution B, as illustrated by a broken line in FIG. 6. As a result, the threshold voltage distribution B and the threshold voltage distribution C cannot be distinguished from each other. In this case, no matter what value is set as the read voltage CR, the read operation cannot be performed.

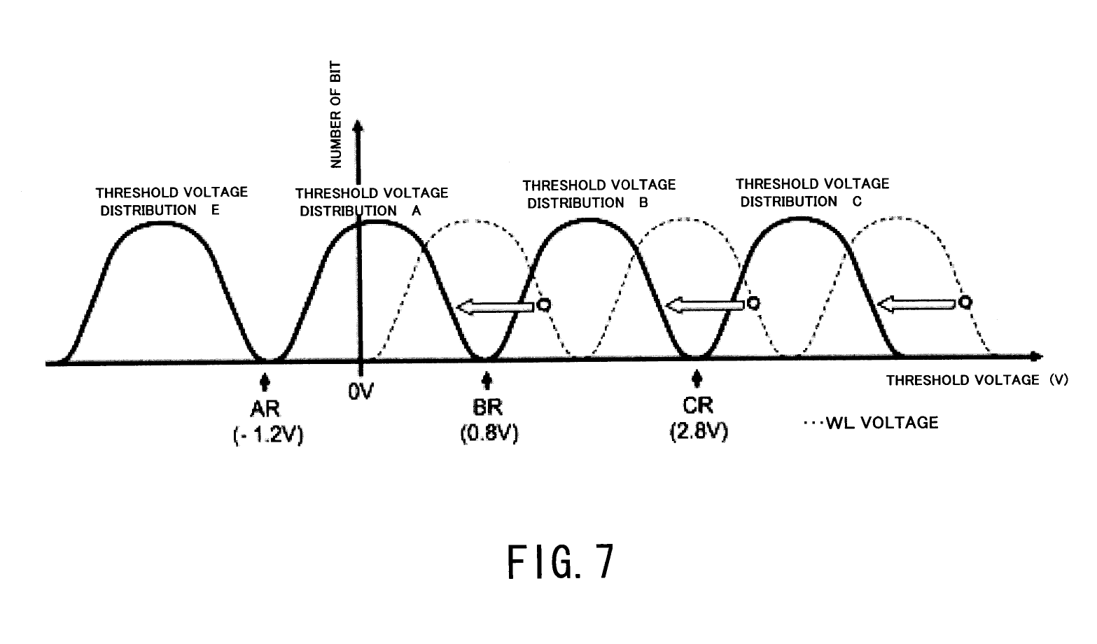

A second comparative example is described. FIG. 7 is a diagram illustrating threshold voltage distributions of each memory cell transistor of the second comparative example.

As illustrated in FIG. 7, the read voltage AR is set to a negative voltage in the second comparative example. The method of the second comparative example is called “a negative sense method”. In the second comparative example, the threshold voltage distribution C is made lower than in the first comparative example, and thereby the electric charge accumulated in the memory cell transistor can be prevented from leaking out. However, the second comparative example requires a negative booster to generate a negative read voltage AR in addition to the positive booster to generate the positive read voltages BR and CR. Moreover, the second comparative example also requires a structure to isolate a P-channel well to which the negative voltage is applied, from a P-channel well to which the ground voltage is applied. As a result, the size reduction of the semiconductor memory device 1 is hampered. Further, manufacturing costs are also increased due to the necessity of a change in the manufacturing process.

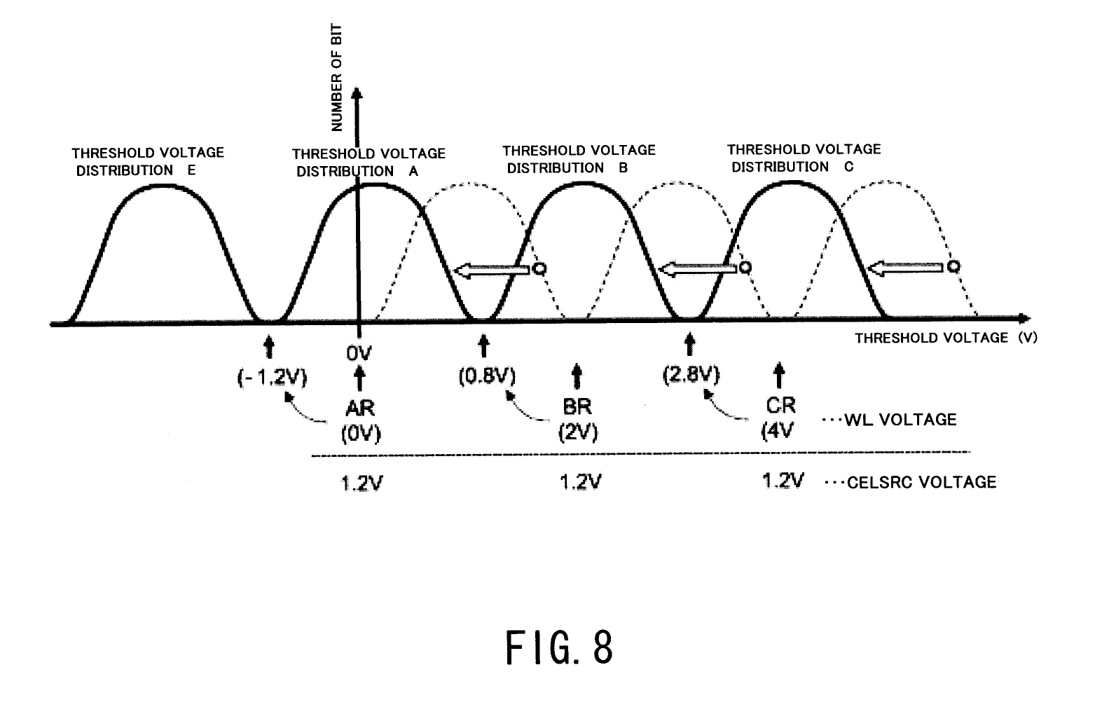

A third comparative example is described. FIG. 8 is a diagram illustrating threshold voltage distributions of each memory cell transistor of the third comparative example.

As illustrated in FIG. 8, the cell source voltage is set to a positive voltage of +1.2V, for example, instead of the ground voltage in the third comparative example. The method of the third comparative example is called “a positive CELSRC method”. In the third comparative example, even when the read voltage AR is set to 0V, the gate voltage (0V) of the selective cell can be made negative relative to the source voltage (+1.2V) of the selective cell. Thus, the third comparative example can obtain a negative read voltage without generating a negative voltage. As a result, the problems associated with the generation of the negative voltage described in the second comparative example can be avoided. Here, a broken line shown in FIG. 4 represents an operation in the third comparative example.

The third comparative example, however, has a problem that, even with an attempt to lock out a NAND string in which the value of the selective cell is determined, the NAND string cannot be certainly locked out because the voltage between gate and source of the N-channel transistor NT3 is lowered by an amount of increase in the cell source voltage as described above in FIG. 5(b). When the NAND string supposed to be locked out cannot be locked out, the bit line BL becomes into the floating state, and interferes with other bit lines. Such interference makes the subsequent read operation unstable, and lowers the operation reliability of the semiconductor memory device. To begin with, the semiconductor memory device may be configured not to lock out the NAND strings so as to avoid the above problem. Such a configuration, however, increases the current consumption. To certainly lock out the NAND string, it is conceivable to use a higher voltage as the power supply voltage VDD. Use of the higher power supply voltage VDD, however, makes it difficult to achieve the scaling-down and energy saving of the semiconductor memory device.

In contrast, in the embodiment, the cell source voltage CELSRC is set to the relatively high voltage V1 only in the “Read-A” where the high cell source voltage CELSRC is needed. In the “Read-A,” the read result for the selective cell is written into the data latch B, and has nothing to do with the voltage INV. As a result, the semiconductor memory device can achieve high operation reliability while not executing the lockout in the “Read-A.” In addition, the “Read-B” and the “Read-C” employ the relatively low voltage V2 as the cell source voltage CELSRC. The read result for the selective cell is written into the data latch A, and the voltage INV shifts according to the read result. Thus, in the “Read-B” and the “Read-C”, the NAND string can be locked out certainly depending on the value of the selective cell. Thus, it is possible to achieve both the high operation reliability and the reduction in the current consumption together.

Here, although the embodiment is described by taking the example where the voltage V2 is set to the ground voltage (0V), the voltage V2 is not limited to the above case but may be any voltage equal to or larger than 0V but lower than the voltage V1. In addition, although the embodiment is described by taking the example where the memory cell transistor 11 is configured to store four levels of values, values to be stored by the memory cell transistor 11 are not limited to the four levels, but may be three levels, or five or more levels. In the latter case, the read operations of identifying the lowest threshold voltage distribution and the second lowest threshold voltage distribution may avoid execution of the lockout while using the voltage V1 as the cell source voltage CELSRC; and the other read operations may execute the lockout while using the voltage V2 as the cell source voltage CELSRC.

Furthermore, when the semiconductor memory device 1 receives a command for a read operation from the memory controller 100 or the host 200, it may be switched a voltage applied to the source line in order to read data.

According to the embodiment described above, a semiconductor memory device having high operation stability can be achieved.

The configuration of the memory cell array is disclosed in U.S. patent application Ser. No. 12/407,403 filed 19 Mar. 2009 and entitled “three dimensional stacked nonvolatile semiconductor memory”. The memory cell array includes a plurality of NAND strings 10 in this embodiment. In addition, the configuration thereof is disclosed in U.S. patent application Ser. No. 12/406,524 filed 18 Mar. 2009 and entitled “three dimensional stacked nonvolatile semiconductor memory”, in U.S. patent application Ser. No. 13/816,799 filed 22 Sep. 2011 and entitled “nonvolatile semiconductor memory device”, and in U.S. patent application Ser. No. 12/532,030 filed 23 Mar. 2009 and entitled “semiconductor memory and method for manufacturing the same”. The entire descriptions of these patent applications are incorporated by reference herein.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a NAND string including a memory cell transistor configured to be capable of holding any of three or more levels of values, the NAND string including one end connected to a bit line and the other end connected to a source line; and
a sense amplifier configured to connect the bit line,
a first voltage being applied to the source line when a first read voltage is applied to a selected word line connected to a selected memory cell transistor, a second voltage being applied to the source line when a second read voltage is applied to the selected word line, the first voltage being higher than the second voltage, the first read voltage being the lowest voltage of a plurality of read voltage, the second read voltage being higher than the first read voltage.

2. The device according to claim 1, wherein a third voltage is applied to the bit line when the first voltage is applied to the source line and a fourth voltage is applied to the bit line after the first voltage is applied to the source line.

3. The device according to claim 1, wherein
any of four levels of values is written in the memory cell transistor,
the first voltage is applied to the source line when the value held in the memory cell transistor falls under the threshold voltage distribution for any of the lowest and second lowest values or the threshold voltage distribution for any of the highest and second highest values, the second voltage is applied to the bit line when the held value is judged as the lowest value or the second lowest value.

4. The device according to claim 1, wherein
the sense amplifier including:
a first transistor including one end connected to the bit line and the other end to which the cell source voltage is applied;
a first data latch; and
a second data latch, wherein
the sense amplifier determines a second hold voltage to be held in the second data latch based on the value read from the memory cell transistor when the sense amplifier judges whether the value held in the memory cell transistor falls under the threshold voltage distribution for the lowest value or the threshold voltage distribution for any of the other values,
the sense amplifier determines a first hold voltage to be held in the first data latch based on the value read from the memory cell transistor when the sense amplifier judges whether the value held in the memory cell transistor falls under the threshold voltage distribution for the highest value or the threshold voltage distribution for any of the other values,
the first hold voltage held in the first data latch is applied to the gate of the first transistor, and
the second hold voltage held in the second data latch is not applied to the gate of the first transistor.

5. The device according to claim 4, wherein
the sense amplifier includes second to fourth transistors connected in series,
the second transistor includes one end to which a power supply voltage is applied and a gate to which the first hold voltage is applied,
the third transistor includes one end connected to the other end of the second transistor and a gate to which a third voltage is applied, and
the fourth transistor includes one end connected to the other end of the third transistor, a gate to which a fourth voltage is applied, and the other end connected to the one end of the first transistor and the bit line.

6. The device according to claim 5, wherein
the first and fourth transistors are N-channel MOSFETs,
the fourth transistor turns off and the drain of the fourth transistor is turned into a floating state when the fourth voltage is a low level.

7. The device according to claim 1, wherein
the NAND string includes a first select transistor, a plurality of memory cell transistors connected in series, and a second select transistor connected in series,
the first select transistor includes one end connected to the bit line and the other end connected to one end of the plurality of memory cell transistors, and
the second select transistor includes one end connected to the other end of the plurality of memory cell transistors and the other end to which the cell source voltage is applied.

8. The device according to claim 1, wherein the second voltage is equal to or higher than a ground voltage.

9. A semiconductor memory device comprising:
a NAND string including a memory cell transistor to which any of four levels of values is written, the NAND string having one end electrically connected to a bit line and the other end electrically connected to a source line; and
a sense amplifier configured to connect the bit line, wherein
the sense amplifier including:
a first transistor having one end connected to the bit line and the other end connected to the source line;
a first data latch configured to generate a first hold voltage and to apply the first hold voltage to a gate of the first transistor; and
a second data latch configured to generate a second hold voltage being a voltage different from the first hold voltage, and configured not to apply the second hold voltage to the gate of the first transistor, and wherein
when a first read voltage is applied to a selected word line connected to a selected memory cell transistor, a first voltage is applied to the source line, the second hold voltage to be held in the second data latch is determined based on the value read from the memory cell transistor,
when a second read voltage is applied to the selected word line, a second voltage that is lower than the first voltage but equal to or higher than a ground voltage is applied to the source line, the first hold voltage to be held in the first data latch is determined based on the value read from the memory cell transistor, and when the value held in the memory cell transistor is judged as any one of the highest and second highest values, the first transistor is held out of conduction, and when the value held in the memory cell transistor is judged as any one of the lowest and second lowest values, the first transistor is brought into conduction and thereby a voltage of the bit line is set to the second voltage,
when the sense amplifier judges whether the value held in the memory cell transistor falls under the threshold voltage distribution for the highest value or the threshold voltage distribution for any of the other values, the second voltage is applied to the source line, the first hold voltage to be held in the first data latch is determined based on the value read from the memory cell transistor, and when the held value is judged as the highest value, the first transistor is held out of conduction, and when the held value is judged as a value other than the highest value, the first transistor is brought into conduction and thereby the voltage of the bit line is set to the second voltage.

10. The device according to claim 9, wherein the second voltage is equal to or higher than a ground voltage.

11. The device according to claim 9, wherein
the NAND string includes a first select transistor, a plurality of memory cell transistors connected in series, and a second select transistor connected in series,
the first select transistor includes one end connected to the bit line and the other end connected to one end of the plurality of memory cell transistors, and
the second select transistor includes one end connected to the other end of the plurality of memory cell transistors and the other end to which the cell source voltage is applied.

12. The device according to claim 9, wherein
the memory cell transistor is an N-channel floating gate transistor or an N-channel transistor having a MONOS structure.

13. The device according to claim 1, wherein
first to third read operations are performed in the semiconductor memory device,
when the first read operation is performed, the first read voltage is applied to the gate of the selected memory cell transistor, the first voltage is applied to the source of the selected memory cell transistor,
when the second read operation is performed, the second read voltage is applied to the gate of the selected memory cell transistor, the second voltage is applied to the source of the selected memory cell transistor,
when the third read operation is performed, a third read voltage being higher than the second read voltage is applied to the gate of the selected memory cell transistor, the second voltage is applied to the source of the selected memory cell transistor.

14. The device according to claim 13, wherein
the first to third read operations in the semiconductor memory device is performed by using “A” only Deep Negative method (AODN method).
